(19) United States
(12) Patent Application Publication
(10) Pub. No.: US 2026/0231488 A1
(43) Pub. Date: Aug. 6, 2026

(54) STRUCTURE WITH SPACER ON INTRINSIC BASE PEDESTAL AND RELATED METHODS

(71) Applicant: GlobalFoundries U.S. Inc., Malta, NY (US)

(72) Inventors: Megan Elizabeth Lydon-Nuhfer, Essex Junction, VT (US); Uppili S. Raghunathan, Essex Junction, VT (US); Jacob M. DeAngelis, Burlington, VT (US); Sarah A. McTaggart, Essex Junction, VT (US); Steven M. Shank, Jericho, VT (US)

(21) Appl. No.: 19/045,068

(22) Filed: Feb. 4, 2025

(51) Int. Cl. H10D 62/13; H10D 10/01; H10D 10/80

(52) U.S. Cl. CPC H10D 62/136; H10D 10/021; H10D 10/821; H10D 62/138

(57) ABSTRACT

The disclosure provides a structure with a spacer on an intrinsic base pedestal, and related methods. A structure of the disclosure includes an intrinsic base pedestal on a collector and adjacent a dielectric layer. A spacer is over the intrinsic base pedestal. The spacer extends vertically upward from and horizontally beyond the intrinsic base pedestal. An emitter is horizontally adjacent the spacer. An extrinsic base includes a first portion vertically between the intrinsic base pedestal and the spacer, and a second portion on the dielectric layer. A vertical thickness of the second portion is less than a vertical thickness of the first portion.

### BACKGROUND

The present disclosure relates to bipolar transistor structures and methods to form such structures.

Internet-of-Things (IOT) devices, wearable devices, smartphone processors, automotive electronics, and radio frequency integrated circuits (RFICs) (including millimeter wave (mmWave) ICs) can benefit from the inclusion of bipolar junction transistors (BJTs) because BJTs tend to have more drive and are generally considered better suited for analog functions than field effect transistors (FETs). BJTs are typically formed as vertical devices (e.g., with an in-substrate collector, a base including an intrinsic base region aligned above the collector region and extrinsic base regions on opposing sides of the intrinsic base region, and an emitter aligned above the intrinsic base region). In such vertical BJT structures, horizontal device scaling to increase the number of devices over a desired surface area can offer significant performance improvements for a device. However, corresponding reductions in the number of processing structures (e.g., masks) may be needed to realize these benefits.

### SUMMARY

The illustrative aspects of the present disclosure are designed to solve the problems herein described and/or other problems not discussed.

Embodiments of the disclosure provide a structure including: an intrinsic base pedestal on a collector and adjacent a dielectric layer; a spacer over the intrinsic base pedestal, wherein the spacer extends vertically upward from and horizontally beyond the intrinsic base pedestal, and an emitter is horizontally adjacent the spacer; and an extrinsic base including: a first portion vertically between the intrinsic base pedestal and the spacer, and a second portion on the dielectric layer, wherein a vertical thickness of the second portion is less than a vertical thickness of the first portion.

Other embodiments of the disclosure provide a structure including: a collector on a sub-collector and adjacent a dielectric layer; an intrinsic base pedestal on the collector and adjacent the dielectric layer, wherein the intrinsic base pedestal includes a set of sloped sidewalls; a spacer over the intrinsic base pedestal, wherein the spacer extends vertically upward from and horizontally beyond the intrinsic base pedestal; an emitter on the intrinsic base pedestal and horizontally adjacent the spacer; and an extrinsic base including: a first portion vertically between the intrinsic base pedestal and the spacer, wherein a lower surface of the first portion of the extrinsic base is adjacent one of the set of sloped sidewalls of the intrinsic base pedestal, and a second portion on the dielectric layer, wherein a vertical thickness of the second portion is less than a vertical thickness of the first portion.

Additional embodiments of the disclosure provide a method including: forming an intrinsic base pedestal on a collector and adjacent a dielectric layer; forming a spacer over the intrinsic base pedestal, wherein the spacer extends vertically upward from and horizontally beyond the intrinsic base pedestal, and an emitter is horizontally adjacent the spacer; and forming an extrinsic base including: a first portion vertically between the intrinsic base pedestal and the spacer, and a second portion on the dielectric layer, wherein a vertical thickness of the second portion is less than a vertical thickness of the first portion.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 depicts a cross-sectional view of a structure according to embodiments of the disclosure.

FIG. 2 depicts an expanded cross-sectional view of a structure according to embodiments of the disclosure.

FIGS. 3-11 depict cross-sectional views of processes in methods to form a structure according to embodiments of the disclosure.

FIGS. 12-14 depict cross-sectional views of processes in methods to form a structure according to other embodiments of the disclosure.

FIGS. 15-21 depict cross-sectional views of processes in methods to form a structure according to additional embodiments of the disclosure.

It is noted that the drawings of the disclosure are not necessarily to scale. The drawings are intended to depict only typical aspects of the disclosure and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

The disclosure provides a structure with a spacer on an intrinsic base pedestal, and related methods. A structure of the disclosure includes an intrinsic base pedestal on a collector and adjacent a dielectric layer. A spacer is over the intrinsic base pedestal. The spacer extends vertically upward from and horizontally beyond the intrinsic base pedestal. An emitter is horizontally adjacent the spacer. An extrinsic base includes a first portion vertically between the intrinsic base pedestal and the spacer, and a second portion on the dielectric layer. A vertical thickness of the second portion is less than a vertical thickness of the first portion.

Bipolar junction transistor (BJT) structures, such as those in embodiments of the disclosure, operate using multiple “P-N junctions.” The term “P-N” refers to two adjacent materials having different types of conductivity (i.e., P-type and N-type), which may be induced through dopants within the adjacent material(s). A P-N junction, when formed in a device, may operate as a diode. A diode is a two-terminal element, which behaves differently from conductive or insulative materials between two points of electrical contact. Specifically, a diode provides high conductivity from one contact to the other in one voltage bias direction (i.e., the “forward” direction), but provides little to no conductivity in the opposite direction (i.e., the “reverse” direction). In the case of the P-N junction, the orientation of a diode's forward and reverse directions may be contingent on the type and magnitude of bias applied to the material composition of one or both terminals, which affects the size of the potential barrier. In the case of a junction between two semiconductor materials, the potential barrier will be formed along the interface between the two semiconductor materials. Generally, a BJT structure includes a base region vertically or horizontally between emitter and collector materials. A BJT can be either a PNP-type BJT or an NPN-type BJT. In a PNP-type BJT, the emitter and collector regions have P-type conductivity and at least a portion of the base region has N-type conductivity. In an NPN-type BJT, the emitter and collector regions have N-type conductivity and at least a portion of the base has P-type conductivity. Additionally, it should be noted that, in a conventional BJT, the same semiconductor material (e.g., silicon) can be used for the base, collector and emitter. Alternatively, a BJT can be a heterojunction bipolar transistor (HBT). In a HBT, the collector and emitter are made, at least in part, of one semiconductor material (e.g., silicon) and the base is made, at least in part, of a different semiconductor material (e.g., silicon germanium). The use of differing semiconductor materials at the emitter-base junction and at the base-collector junction creates heterojunctions suitable for handling higher frequencies.

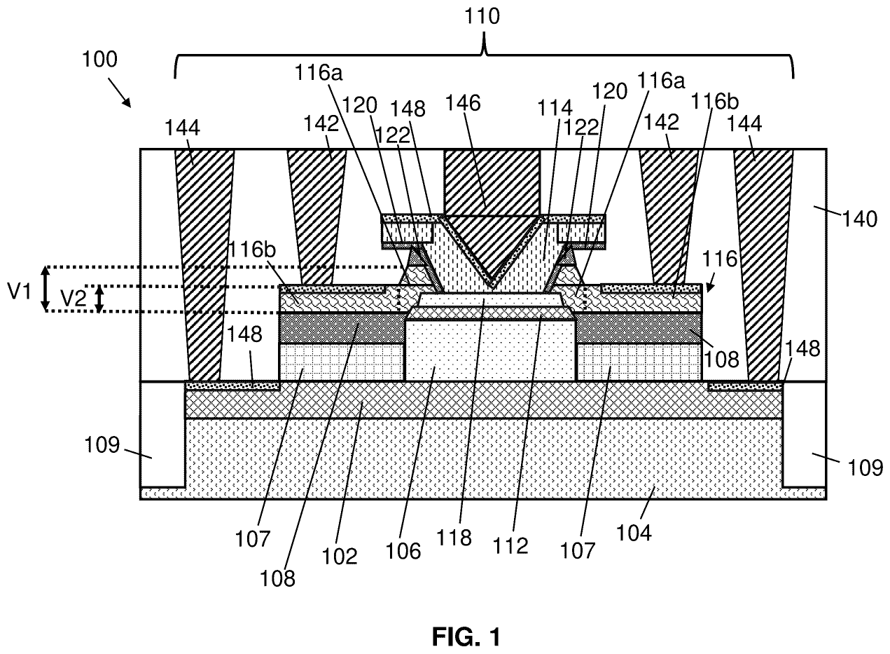

Referring to FIG. 1, a structure 100 according to the disclosure may include: a bipolar transistor (also abbreviated as a “BJT” to indicate “bipolar junction transistor,”) 110. Bipolar transistor 110 can, optionally, be a heterojunction bipolar transistor (HBT). In any case BJT can be, e.g., a vertically oriented bipolar transistor as discussed herein, in which a spacer is on an intrinsic base pedestal and extends vertically upward from, and horizontally beyond, the intrinsic base pedestal. In various implementations, the spacer in this configuration includes a spacer protrusion on a sidewall of the spacer and vertically above an underlying portion of the extrinsic base of the BJT. Structure 100 may be formed on a subcollector 102 (i.e., a doped portion of a semiconductor substrate) including, e.g., one or more monocrystalline semiconductor materials. Subcollector 102 may include but is not limited to silicon, germanium, silicon germanium (SiGe), silicon carbide, or any other common integrated circuit (IC) semiconductor substrates. In the case of SiGe, the germanium concentration in subcollector 102 may differ from other SiGe-based structures described herein. A portion or entirety of subcollector 102 may be strained. Subcollector 102 may be doped (i.e., it may define a “doped well”), e.g., to enable coupling to the lower active semiconductor materials of a vertical bipolar transistor. Subcollector 102 may have any conceivable doping type and/or doping composition appropriate for use within and/or coupling to the collector terminal of a bipolar transistor. For instance, subcollector 102 may have the same dopant type as a collector 106 formed thereon, e.g., P-type doping in the case of a PNP-type BJT or N-type doping in the case of an NPN-type BJT, and/or may have a higher or lower dopant concentration therein.

Collector 106 may be on subcollector 102, e.g., as a single layer or multiple similarly doped but distinct layers formed by epitaxial deposition of silicon, SiGe, and/or other semiconductor materials on subcollector 102 and may have a predetermined doping type, e.g., by being doped in-situ or during formation of semiconductor material(s) of subcollector 102 and/or subcollector 102. Collector 106 is monocrystalline in structure. Collector 106 may define active semiconductor material of a vertical bipolar transistor and thus may be vertically below other terminals (i.e., base, including extrinsic and intrinsic base regions, and emitter terminals discussed herein) of bipolar transistor 110. Collector 106 is illustrated as having vertical sidewalls over subcollector 102. However, collector 106 may have other shapes (e.g., sloped sidewalls, curved sidewalls, etc.) as a result of varying manufacturing techniques.

Structure 100 includes a set of dielectric layers 107, 108 on subcollector 102 for additional electrical and physical separation of bipolar transistor 110 from other components. Each dielectric layer 107, 108 may be horizontally adjacent a respective side of collector 106, and/or may horizontally surround collector 106 outside the cross-section shown. Although any number of dielectric layers 107, 108 may be present, two are shown as an example. According to an example, dielectric layer 107 on subcollector 102 may be one or more oxide-based insulators (e.g., silicon dioxide (SiO₂)), or other materials having similar properties. Dielectric layer 108 on dielectric layer 107 may be one or more nitride-based insulators (e.g., silicon nitride (SiN)) or other materials having similar properties but other combinations are possible. In some cases, only one dielectric layer (i.e., only one of layer 107 or layer 108) may be present, and/or additional layers may be present to provide an oxide-nitride-oxide (ONO) stack or other combination of insulative materials on subcollector 102.

However embodied, dielectric layer(s) 107, 108 may extend above subcollector 102 to at least the height of collector 106 over subcollector 102. Alternatively, dielectric layer(s) 107, 108 may extend above subcollector 102 to above the height of collector 106 over subcollector 102. Dielectric layers 107, 108 optionally may also be horizontally alongside portions of an intrinsic base pedestal 112 thereon. Dielectric layers 107, 108 may be formed, e.g., by deposition of desired material(s) on subcollector 102, trench isolations (TIs) 109 adjacent subcollector 102, etc. Depending on the shape of dielectric layer(s) 107, 108, collector 106 when formed may have a tapered or sloped shape, e.g., with tapered sidewalls. In cases where collector 106 has tapered sidewalls, various materials on collector 106 (e.g., intrinsic base pedestal 112 discussed herein) also may have tapered sidewall profiles, e.g., by selective epitaxial growth of additional material on collector 106.

Structure 100 also may include trench isolations (TIs) 109, which optionally may be subdivided into multiple layers and/or materials of varying width and/or depth, and may also be on subcollector 102 to horizontally separate various active semiconductor materials on substrate 104. As shown, some TIs 109 may extend vertically into substrate 104, whereas others may be located on subcollector 102 to prevent electrical shorting between subcollector 102 and overlying areas of bipolar transistor 110. As discussed elsewhere herein, TI 109 initially may extend over substrate 104 as a single layer. Portions of TI 109 may be removed to form a trench, which may undercut certain remaining portions of TI 109 near subcollector 102. The undercut portions of TI 109 may form substantially triangular cavities, recesses, etc.

Bipolar transistor 110 may include a base terminal including, collectively, an intrinsic base pedestal 112 on collector 106 and an extrinsic base 116 coupled to intrinsic base pedestal 112. Intrinsic base pedestal 112 and extrinsic base 116 may have different properties but function in bipolar transistor 110 as a single terminal. As illustrated, intrinsic base pedestal 112 extends vertically upward from collector 106 and adjacent dielectric layer(s) 107, 108 to create an upwardly protruding structure (i.e., a “pedestal”). Intrinsic base pedestal 112 may have inwardly tapered sidewalls such that the top surface of intrinsic base pedestal 112 is narrower in width than the top surface of collector 106. Intrinsic base pedestal 112 may include, e.g., monocrystalline SiGe or any other monocrystalline semiconductor material that is doped to have a predetermined polarity. Intrinsic base pedestal 112 may include a different semiconductor material (e.g., silicon germanium as opposed to silicon) than collector and 106 and an emitter 114 thereover. The use of differing semiconductor materials at the emitter-base junction and at the base-collector junction creates heterojunctions, which are, for example, suitable for handling higher frequencies. In this case, the BJT is referred to in the art as an HBT as noted herein. In the case where the bipolar transistor is an NPN-type transistor and subcollector 102, collector 106, and emitter 114 are doped n-type, intrinsic base pedestal 112 may be doped p-type to form a P-N junction, and hence a base-to-collector interface. It is also understood that intrinsic base pedestal 112 may be doped n-type in the case where the bipolar transistor is a PNP-type transistor. However embodied, intrinsic base pedestal 112 may extend to a predetermined height over collector 106.

Intrinsic base pedestal 112 may be structurally and compositionally distinct from other portions of a base terminal for bipolar transistor 110. Intrinsic base pedestal 112 in particular may be lightly doped, or possibly undoped, whereas an extrinsic base 116 elsewhere in bipolar transistor 110 may be more highly doped than intrinsic base pedestal 112. Intrinsic base pedestal 112 may be formed, e.g., by forming a layer of semiconductor material, which may be monocrystalline silicon or SiGe as discussed herein, on collector 106. Additional semiconductor material may be formed to create intrinsic base pedestal 112 through selective epitaxial growth and/or similar processes to form additional semiconductor material while preserving the crystallographic orientation and/or composition of the underlying material(s). Selective epitaxial growth of intrinsic base pedestal 112, in particular, may maintain the shape and orientation of the sidewalls of collector 106.

Intrinsic base pedestal 112 also may include a semiconductor film 118 on its upper surface to enable deposition and growth of other semiconductor material(s) of different conductivity types elsewhere in the forming of structure 100. Semiconductor film 118 may include, e.g., non-doped silicon (Si) or lightly doped silicon (Si) in various crystalline forms, e.g., single crystallographic orientation Si, polycrystalline Si, etc. In some implementations, semiconductor film 118 may be known as an “intrinsic semiconductor” material. As discussed herein, semiconductor film 118 may be considered to be a part of intrinsic base pedestal 112 and may be formed by forming intrinsic base pedestal 112 material to a desired height before forming semiconductor film 118 thereon, and/or by removing a portion of intrinsic base pedestal 112 material for replacement with semiconductor film 118. Semiconductor film 118 may also be formed by any other currently known or later developed technique to form transitional semiconductor material suitable for subsequent forming of extrinsic base 116 and/or emitter 114 material thereon, having varying conductivity types and/or dopant concentrations. Semiconductor film 118 may function, electrically, as a part of intrinsic base pedestal 112 but may have a different composition to function as an etch stop layer to control the location and size of emitter 114. Thus, singular references to intrinsic base pedestal 112 herein may refer to intrinsic base pedestal 112 and semiconductor film 118, collectively.

The base terminal of bipolar transistor 110 may also include extrinsic base(s) 116 on outer portion(s) of intrinsic base pedestal 112. Extrinsic base(s) 116 may include a polycrystalline semiconductor (e.g., polycrystalline SiGe) with a relatively high amount of the same doping type as (e.g., more p-type doping than) intrinsic base pedestal 112. Extrinsic base(s) 116 may be formed, e.g., by depositing an initial (seed) layer of monocrystalline and/or other semiconductor materials on intrinsic base pedestal 112. Through selective epitaxial growth, deposition, and/or other processing, extrinsic base(s) 116 can be formed from the initial layer to a desired height. Extrinsic base 116, by being formed through selective epitaxial growth may have sidewalls that are similarly shaped and/or substantially aligned with the sidewalls of intrinsic base pedestal 112 (and perhaps collector 106) thereunder. As discussed in further detail herein, extrinsic base 116 may be subdivided into a first portion 116a (e.g., an inner portion adjacent intrinsic base pedestal 112) and a second portion 116b (e.g., an outer portion 116b located horizontally away from intrinsic base pedestal 112). Each portion 116a, 116b may have distinct physical characteristics (e.g., different vertical thicknesses) arising in part from various structural and processing aspects of spacer(s) 120 thereover.

Emitter 114 may be on the center portion of intrinsic base pedestal 112. In an example, portions of emitter 114 may be horizontally between portions of extrinsic bases 116 that extend horizontally outward from, and vertically above, semiconductor film 118. A set of spacers 120 located adjacent emitter 114 may electrically isolate emitter 114 from extrinsic bases 116. Emitter 114 may be formed on and above intrinsic base pedestal 112, e.g., by forming a stack of materials including portions of extrinsic base(s) 116, removing a portion of the stack of materials, and forming emitter 114 and/or other components within and/or in place of the removed extrinsic base 116 material. Emitter 114 may have the same doping type as subcollector 102 and collector 106, and thus, has an opposite doping type relative to extrinsic base 116 (and intrinsic base pedestal 112, if doped). In the case where bipolar transistor 110 is an NPN device, collector 106 and emitter 114 may be doped n-type to provide the two n-type active semiconductor materials and intrinsic base pedestal 112 may be doped p-type. Emitter 114 may include polycrystalline silicon and/or other monocrystalline semiconductor materials, including one or more materials used elsewhere in structure 100 to form subcollector 102, collector 106, extrinsic base 116 (with different doping), etc.

Structure 100 includes one or more spacers 120 adjacent emitter 114, vertically interfacing with an upper surface of intrinsic base pedestal 112 (e.g., on semiconductor film 118 thereof). Although one spacer 120 is shown adjacent each sidewall of emitter 114, such spacers 120 may include multiple layers of material in a variety of arrangements. Other compositions and/or arrangements of spacers 120 currently known or later developed also may be used. Spacer(s) 120 may include oxide materials, nitride materials, and/or any other insulative material discussed herein, e.g., compositions similar to TI 109 or other insulating structures. In some implementations, spacer(s) 120 may include a single layer or more than two layers. Spacers 120 may have different compositions to control (e.g., increase) the electrical insulation between emitter 114 and extrinsic base 116.

Spacer(s) 120 may extend vertically upward from, and horizontally beyond, intrinsic base pedestal 112. Each spacer 120 may extend horizontally outward from intrinsic base pedestal 112 in the illustrative example of FIG. 1. Spacers 120 in such a configuration may define a substantial “V-shape” without a bottom point in the cross-section shown between opposite horizontal ends of subcollector 102. In this case, emitter 114 may be horizontally enclosed within spacers 120. Spacers 120 thus may define an insulative barrier between emitter 114 and extrinsic base 116 in both horizontal and vertical directions due to its substantially diagonal orientation. Some portions of spacers 120, in addition, may extend substantially horizontally outwardly from emitter 114 and intrinsic base pedestal 112 thereunder. In such cases, spacers 120 may be vertically above extrinsic base 116 and thus may overlie extrinsic base 116. The shape of spacers 120 may cause emitter 114 therein to similarly have a recess in which emitter contact 146 is formed. Various processes operable to form spacer(s) 120 in a shape that extends vertically above and horizontally beyond intrinsic base pedestal 112 are described elsewhere herein relative to various processing techniques.

Structure 100 may include an inter-level dielectric (ILD) layer 140 over TI 109, extrinsic bases 116, emitter 114, spacers 120, etc. ILD layer 140 may include the same insulating material as TI 109 or may include a different electrically insulative material for vertically separating active materials from overlying materials, e.g., various horizontally extending wires or vias. ILD layer 140 and TI 109 nonetheless constitute different components, e.g., due to TI 109 being vertically between subcollector 102 and the various active components of structure 100. ILD layer 140 may be formed by deposition and/or other techniques to provide electrically insulating materials, and can then be planarized (e.g., using chemical mechanical planarization (CMP)), such that its upper surface remains above any active components formed on subcollector 102. One or more barrier layers (not shown) including, e.g., nitride-based dielectric materials (such as silicon nitride (SiN)) may be on ILD layer 140 to separate it from overlying materials and/or to enable certain portions of structure 100 to be formed and processed differently from each other to affect the shape of conductive contacts to bipolar transistor 110.

A set of base contacts 142 extending through ILD layer 140 may provide the vertical electrical coupling between extrinsic base 116 and overlying metal wires and/or vias. Base contacts 142, notably, do not extend to intrinsic base pedestal 112. Intrinsic base pedestal 112 thus are coupled to base contacts 142 only through extrinsic base 116. Before ILD 140 is formed, some portions of extrinsic base 116 may be converted into a silicide layer 148 to improve conductivity between each base contact 142 and any portions of extrinsic base 116 thereunder, e.g., by providing a conductive metal such as cobalt (Co), titanium (Ti), nickel (Ni), platinum (Pt), or similar material on the upper surface(s) of a targeted material. The conductive material(s) may be annealed while in contact with the underlying semiconductor to produce silicide layer 148 for electrically coupling semiconductor materials to any contacts formed thereon. Excess conductive material can then be removed using any now known or later developed solution, e.g., etching.

Structure 100 also includes an emitter contact 146 to emitter 114 and a collector contact 144 to collector 106 through subcollector 102. Each contact 146, 144 may also be coupled to emitter 114 or subcollector 102, respectively, through silicide layers 148 formed therein. Each contact 142, 144, 146 may also extend through ILD layer 140, thus electrically connecting active semiconductor material within subcollector 102 or emitter 114 to overlying metal wires, vias, etc., above structure 100. Contact(s) 142, 144, 146 optionally may be formed as part of a single operation, e.g., by removing portions of ILD layer 140 to form openings and filling the openings with metal to define each contact 142, 144, 146. One or more of contacts 142, 144, 146 may include refractory metal liners (not separately shown) on their sidewalls to impede or prevent electromigration degradation, shorting to other components, etc.

Some portions of subcollector 102, emitter 114, and extrinsic base 116 may be converted into a silicide layer 148 to improve conductivity between each contact 142, 144, 146 and any active material thereunder, e.g., by providing a conductive metal such as cobalt (Co), titanium (Ti), nickel (Ni), platinum (Pt), or similar material on the upper surface(s) of a targeted material. The conductive material(s) may be annealed while in contact with the underlying semiconductor to produce silicide layer 148 for electrically coupling semiconductor materials to any contact(s) formed thereon. Excess conductive material can then be removed using any now known or later developed solution, e.g., etching.

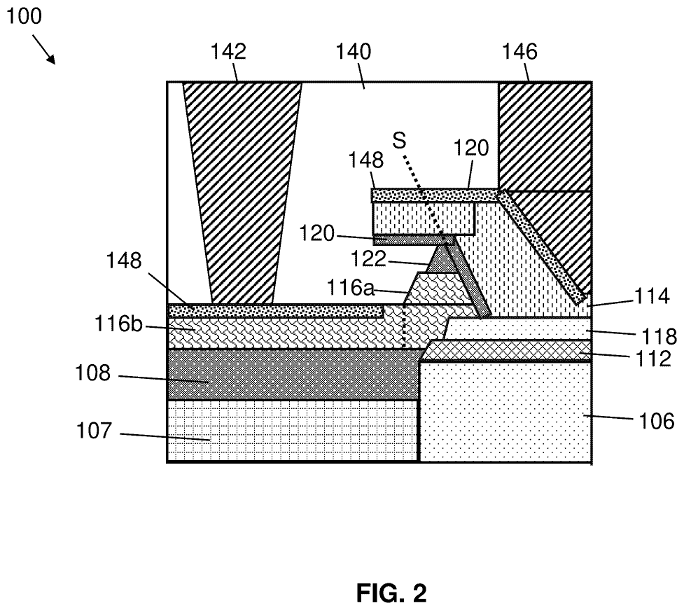

Referring to FIGS. 1 and 2 together, in which FIG. 2 provides an expanded cross-sectional view of extrinsic base 116 within structure 100, additional features of structure 100 are described hereafter. Extrinsic base 116 may be subdivided into a first portion 116a and a second portion 116b, based on relative position and structural aspects of extrinsic base 116 within those positions. It is understood that the composition of extrinsic base 116 may be substantially uniform within first portion 116a, 116b, and that portions 116a, 116b are distinguishable from each other solely based on other specific structural features (vertical thickness, position relative to other components, and/or other features) discussed herein.

First portion 116a may be the subsection of extrinsic base 116 located vertically between intrinsic base pedestal 112 and spacer 120. First portion 116a thus is bordered by dashed lines in FIG. 1, but these dashed lines are solely to indicate a possible boundary between first portion 116a, 116b and not a compositional difference or physical interface. Second portion 116b thus indicates the subsection of extrinsic base 116 located vertically on dielectric layer(s) 107, 108 instead of intrinsic base pedestal 112. Second portion 116b also may have a vertical thickness V2 that is less than a vertical thickness V1 of first portion 116a. That is, first portion 116a may have a larger vertical thickness V1 than vertical thickness V2 by being bounded in part by the diagonally upward shape of spacer 120. By comparison, vertical thickness V2 is less than vertical thickness V1 because second portion 116b may be bounded by an inter-level dielectric (ILD) layer 140 on its upper surface. By contrast, overlying portions of emitter 114 and spacer 120 may vertically separate first portion 116a from ILD layer 140.

Spacer 120 also may include a spacer protrusion 122 on its sidewall, vertically above first portion 116a of extrinsic base 116. Spacer protrusion 122 is an additional, expanded area of spacer 120 material located vertically below and horizontally beyond an adjacent portion of spacer 120, e.g., defining an area of spacer material having a greater horizontal and vertical thickness than other portions of spacer 120. Spacer protrusion 122, as discussed herein, may be a structural artifact of forming multiple areas of spacer material and may provide additional structural and electrical separation between extrinsic base 116 and emitter 114. Spacer protrusion 122 may be located fully vertically beneath emitter 114, e.g., such that no portion of spacer protrusion 122 extends horizontally beyond the horizontal span of emitter 114 thereover. Spacer protrusion 122 may be located alongside a diagonally sloped sidewall of spacer 120, such that spacer protrusion 122 also has a diagonally sloped sidewall.

According to the example shown in FIG. 2, sidewall S of spacer 120 and spacer protrusion 122 may be upwardly and outwardly sloped relative to the location of first portion 116a of extrinsic base 116. Spacer(s) 120 may include a lower surface that is on semiconductor film 118, such that spacer(s) 120 extend diagonally upwardly away from semiconductor film 118. Spacer protrusion 122 is thus adjacent to, and extends alongside, the underside of a lower portion of spacer 120. Spacer 120 also may extend horizontally beyond its uppermost vertical extent, e.g., such that spacer 120 is oriented along multiple orientations. In the FIG. 2 example, spacer 120 has a non-linear profile that is sloped alongside spacer protrusion 122 and extends horizontally over first portion 116a of extrinsic base 116. Although one spacer 120 and spacer protrusion 122 are shown in the magnified view of FIG. 2, FIG. 1 emphasizes that multiple spacers 120 and spacer protrusions 122 may be present alongside respective areas of emitter 114.

Referring to FIG. 1, emitter 114 in structure 100 may have additional structural features arising from the shape and configuration of other components (e.g., spacer(s) 120 and spacer protrusion(s) 122). For instance, where spacer 120 is oriented vertically diagonally upward from semiconductor film 118, emitter 114 may have a similar shape. Inner portions of emitter 114 horizontally bounded by spacer(s) 120 may have sloped outer sidewalls, whereas horizontally outer portions of emitter 114 may have a substantially rectangular profile and extend horizontally over spacer(s) 120 and ILD 140. Horizontally outer portions of emitter 114 thus may be vertically above extrinsic base 116, e.g., such that second portions 116b of extrinsic base 116 are vertically below emitter 114. In other implementations, all of emitter 114 may have an inwardly tapered inner portion defining a valley between outer portions. During manufacture, inner portions of emitter 114 may be removed and/or otherwise may be formed to include an opening within emitter 114. Interior surfaces of the opening and upper surfaces of emitter 114 may be converted into silicide layer 148, and portions of the opening can be filled with conductive material(s) to provide emitter contact 146 to bipolar transistor 110.

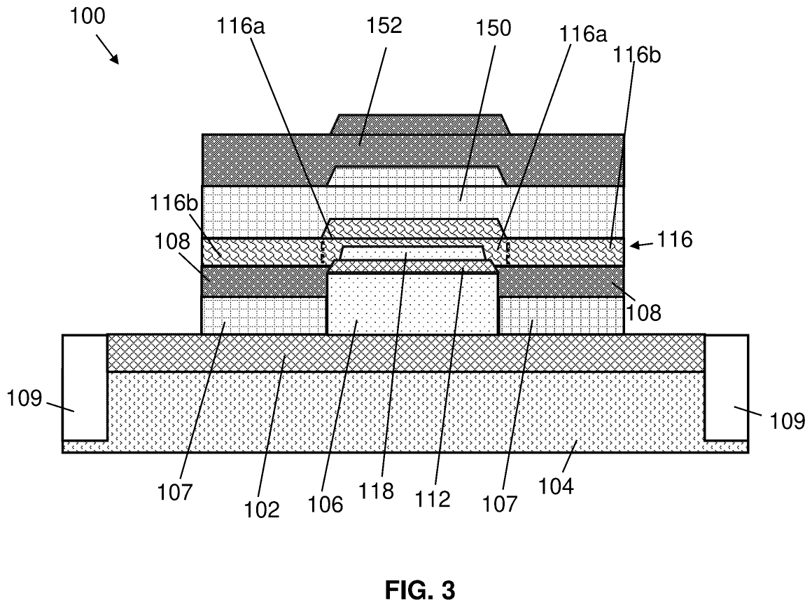

Turning to FIG. 3, methods of forming structure(s) 100 (FIGS. 1, 2) according to any configuration discussed herein are provided. Initial phases of processing may include forming subcollector 102 on substrate 104 (e.g., by targeted doping of semiconductor material to desired concentrations), forming TI(s) 109 and/or other isolating materials adjacent subcollector 102 and substrate 104, etc. Further processing may include forming dielectric layers 107, 108 with TI(s) 109 on subcollector 102, e.g., by forming layers of insulating material on substrate 104 and subcollector 102 by deposition or other currently known or later developed techniques to provide insulator materials. To form collector 106, an opening (not shown) can be formed within the deposited dielectric layer(s) 107, 108 and active semiconductor material can be formed within the opening, e.g., by epitaxial growth and doping of semiconductor material on subcollector 102 within the opening. In the case of forming by epitaxial growth, collector 106 may have sidewall shapes dependent on the shape of dielectric layer(s) 107, 108, the manner of growth implemented and/or the crystallographic orientation of subcollector 102 thereunder. Collector 106 may not completely horizontally fill the opening within dielectric layer(s) 108 once formed, e.g., by controlling the amount of deposition time and/or etching back collector 106 material once it is formed.

Further processing may include, e.g., forming intrinsic base pedestal 112 as a monocrystalline semiconductor material on collector 106. Intrinsic base pedestal 112 may be undoped or have an opposite doping type from collector 106, and in addition, may have a lower concentration of dopants therein. Collector 106 and/or intrinsic base pedestal 112 may be doped through implantation and/or other currently known or later developed doping techniques. The forming of intrinsic base pedestal 112 may begin only after collector 106 is at or near the height of dielectric layer(s) 108 above subcollector 102. Semiconductor film 118 may then be created by non-selective forming of, e.g., a layer of semiconductor material, doped during growth or after growth in situ to have the same conductivity as intrinsic base pedestal 112, with a different composition and/or crystallographic orientation on intrinsic base pedestal 112. Semiconductor film 118 may be formed such that it is located at least partially above adjacent upper surfaces of dielectric layers 108. Semiconductor film 118 may be doped by any conceivable process, e.g., by thermal anneal after semiconductor film 118 is formed. In subsequent processing, semiconductor film 118 may function as a part of intrinsic base pedestal 112 but also may provide an etch stop layer to control the location and size of emitter 114 (FIGS. 1-5), as described in various embodiments herein.

FIG. 3 also depicts extrinsic base 116 on semiconductor film 118 and intrinsic base pedestal 112. Different portions of extrinsic base 116 can be formed by different types of processing. For instance, portions of extrinsic base 116 can be initially formed by selective epitaxial growth of silicon germanium (SiGe) or similar materials on semiconductor film 118. During this phase, extrinsic base 116 is not formed on adjacent portions of dielectric layer(s) 107, 108. Continued processing can include non-selective epitaxial growth of additional SiGe or similar semiconductor materials on the previously grown portions of extrinsic base 116, thereby forming additional extrinsic base 116 material on adjacent surfaces of dielectric layer(s) 107, 108 in addition to portions of extrinsic base 116 that have already been formed. The resulting extrinsic base 116 material thus includes first portion 116a over semiconductor film 118 and second portion 116b over dielectric layer(s) 107, 108, each portion 116a, 116b having a different vertical thickness as described herein. Extrinsic base 116 having different thicknesses in each portion 116a, 116b enables spacer(s) 120 (FIGS. 1, 2) and spacer protrusion(s) 122 (FIGS. 1, 2) to be formed in subsequent processing via any of several techniques discussed herein.

To prepare for forming of other components of bipolar transistor 110 (FIGS. 1, 2), methods of the disclosure include forming an overlying insulator 150 (e.g., one or more oxide-based insulators and/or other materials discussed relative to dielectric layer(s) 108 and/or TI(s) 109) on intrinsic base 116 and a spacer layer 152 (e.g., a nitride based insulator and/or other materials discussed relative to spacer(s) 120) on overlying insulator 150. Overlying insulator 150 may have the same composition(s) as dielectric layer(s) 107, 108, and/or TI(s) 109 but is shown with different cross-hatching from layer(s) 108 and TI(s) 109 for clarity of illustration. However embodied, overlying insulator 150 and spacer layer 152 may be formed by deposition and/or other non-selective processes to form insulating material, thereby substantially replicating the geometry and topography of extrinsic base 116. As shown, overlying insulator 150 and spacer layer 152 initially have raised surfaces vertically above first portion 116a of extrinsic base 116 and semiconductor film 118 thereunder.

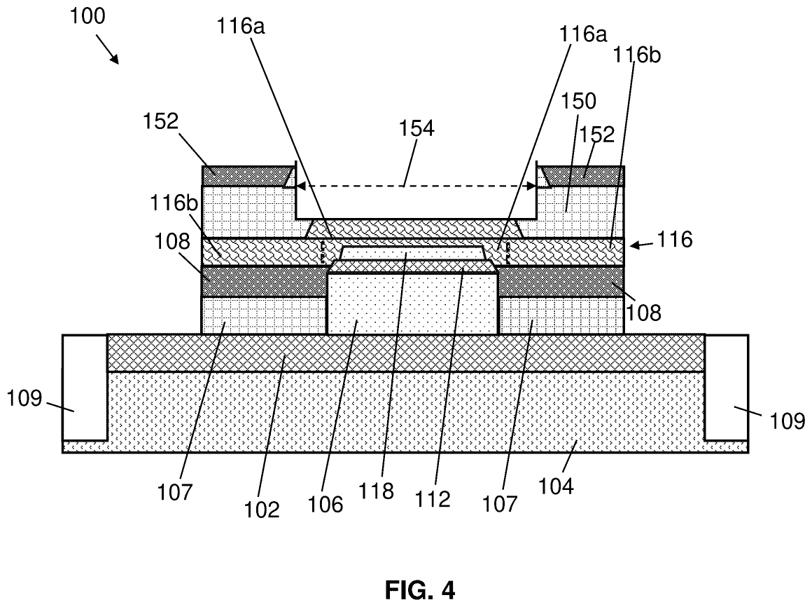

Turning to FIG. 4, further processing may include forming an opening 154 within overlying insulator 150 and spacer layer 152 to re-expose upper surfaces of extrinsic base 116. According to an example, planarization can be performed on overlying insulator 150 and spacer layer 152, causing spacer layer 152 to split into two different spacer layers 152 each having an upper surface substantially planar with an adjacent portion of overlying insulator 150. Opening 154 then can be formed within overlying insulator 150, e.g., by vertical etching of the exposed upper surface(s) of overlying insulator 150 and placing a hard mask nitride material over spacer layers 152. Opening 154, once formed, may uncover extrinsic base 116 and optionally may extend horizontally beyond extrinsic base 116. The vertical etching (e.g., using reactive ion etching) may not affect the composition of spacer layers 152 (e.g., it may be selective to nitride-based insulators) and may be timed such that extrinsic base 116 is substantially unaffected. In other implementations, extrinsic base 116 may function as an “etch stop layer” in the case where overlying insulator 150 is removed with etchants selective to the dielectric composition of overlying insulator 150. Sidewalls of opening 154 may be entirely adjacent overlying insulator 150, e.g., because a portion of overlying insulator 150 may remain intact horizontally between opening 154 and each spacer layer 152.

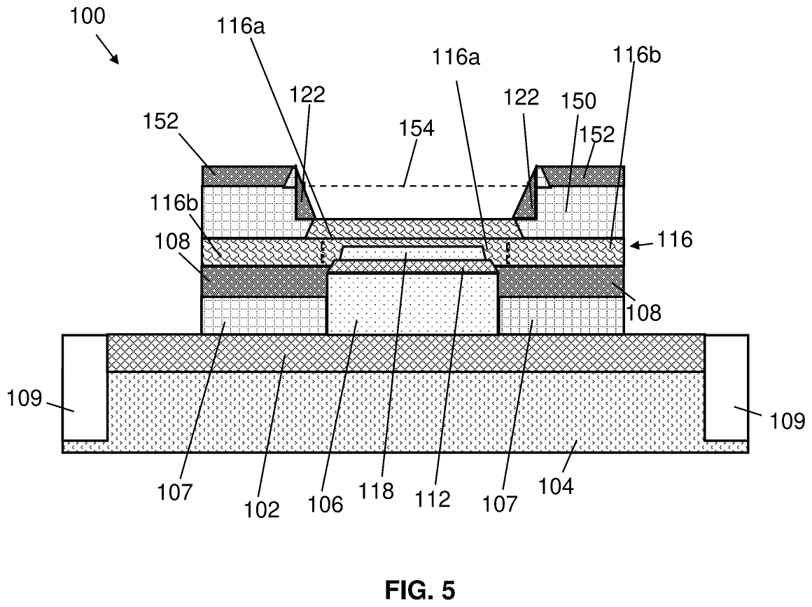

FIG. 5 depicts forming spacer protrusions 122 within opening 154, e.g., on first portion 116a of extrinsic base 116 alongside sidewalls of overlying insulator 150. Spacer protrusions 122 may be formed, e.g., by conformal deposition of nitride-based insulative material(s) on exposed surfaces and vertically re-etching the deposited material(s) such that only spacer protrusion 122 remains intact on sidewalls of overlying insulator 150 within opening 154. Thus, although spacer(s) 120 have not yet been formed, their adjacent spacer protrusion(s) 122 may be formed first over first portion 116a of extrinsic base 116. Spacer protrusion(s) 122 may be formed first, e.g., to enable the subsequent forming of diagonally oriented spacer(s) 120 in structure 100 (FIGS. 1, 2). The non-selective deposition and subsequent vertical etching of spacer material to create spacer protrusion(s) 122 will cause a majority of opening 154 to remain vacant after spacer protrusion(s) 122 are formed.

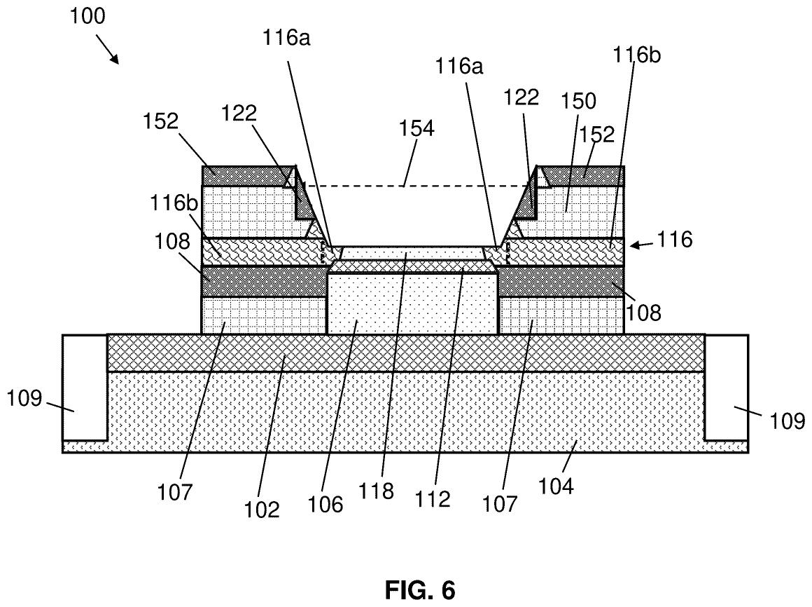

FIG. 6 depicts further processing, e.g., to deepen opening 154. According to an example, methods of the disclosure may include performing a selective etch (e.g., using a vaporous etchant such as hydrochloric acid (HCl) or wet etchants such as ammonium hydroxide(NH₄OH)) to deepen opening 154. Such etching may remove exposed areas of extrinsic base 116 but leave adjacent portions of spacer protrusion 122 and/or spacer layer(s) 152 substantially intact. Wet etching, in addition, may extrapolate the geometrical profile of opening 154 into removed portions of extrinsic base 116. For instance, where opening 154 is substantially trapezoidal, the removed portions of extrinsic base 116 also may define a trapezoidal shape with substantially diagonal sidewalls. The deepened opening 154 may cause a portion of semiconductor film 118 to become exposed at the bottom of opening 154, e.g., to enable forming of a heterojunction or other interface from base to emitter in later stages of processing.

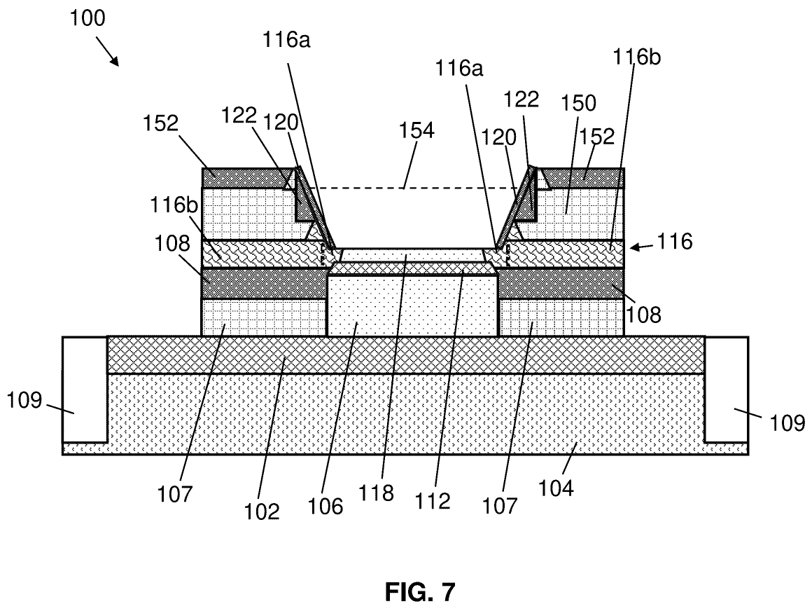

Referring to FIG. 7, with opening 154 deepened to the upper surface of semiconductor film 118, additional insulative materials can be formed. For example, a portion of spacers 120 can then be formed within opening 154, e.g., by depositing a layer of additional spacer material on the partially formed structure to a desired thickness. The additional spacer material can be removed by another instance of vertical etching (e.g., reactive ion etching (RIE)). The vertical etching, as also described, does not remove any portions of the additional spacer material covering sidewalls of opening 154, and thereby forms spacers 120 adjacent opening 154. After spacers 120 are formed, spacer layers 152 may remain intact alongside opening 154 and the upper surface of semiconductor film 118, again, may be exposed within opening 154.

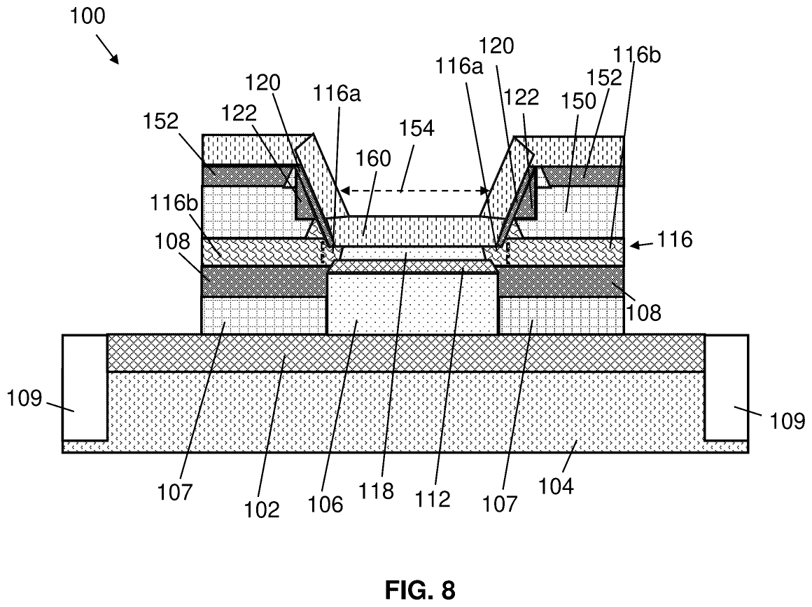

FIG. 8 depicts forming an emitter layer 160, e.g., doped polycrystalline silicon (“polysilicon”), on semiconductor film 118, spacers 120, and spacer layers 152. Emitter layer 160 may be formed, e.g., by non-selective deposition and doping of semiconductor material(s) thereon. Emitter layer 160, when initially formed, may be substantially U-shaped or V-shaped as a result of being formed partially within opening 154. Emitter layer 160, when formed by deposition, may not completely fill opening 154. Emitter layer 160 in other embodiments discussed herein may completely fill opening 154 (e.g., when emitter layer 160 is formed by deposition and subsequent planarization).

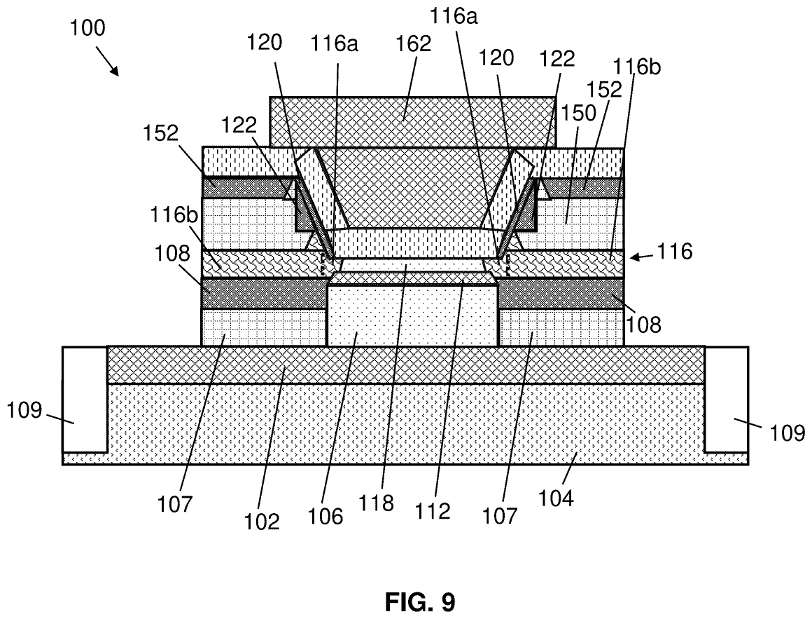

FIG. 9 depicts further materials formed to prepare the structure for silicidation and/or contact formation. With emitter layer 160 in place, an emitter mask 162 can be formed on emitter layer 160 and within opening 154 (FIGS. 4-8) to fill opening 154. Emitter mask 162 may include any currently known or later developed photoresist material, and/or other dielectric structures configured to protect underlying materials (e.g., emitter layer 160) from being removed in subsequent processing. Other materials not covered by emitter mask 162 can be contacted and removed by etchants in subsequent processing.

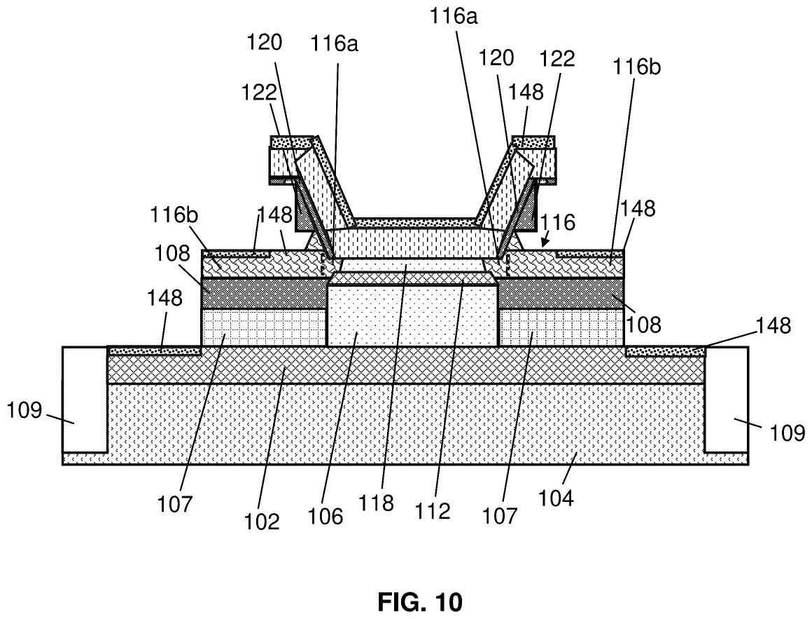

FIG. 10 depicts the result of several subsequent operations: removing any materials not covered by emitter mask 162 (FIG. 9), removing emitter mask 162 itself, and forming silicide layers 148 on exposed areas of subcollector 102, second portion(s) 116b of extrinsic base 116, and emitter 114. With emitter mask 162 in place, outer portions of spacer overlying insulator 150, spacer layer 152, and emitter layer 160 may be removed (e.g., by selective or non-selective etching of their compositions). The remaining portions of these materials, where applicable, may define spacer 120 and emitter 114 over semiconductor film 118. In this configuration, emitter 114 and spacer 120 each may have non-linear shapes. Emitter 114, in particular, have horizontally outer areas of emitter 114 located above the horizontally inner areas of emitter 114. Spacer protrusions 122, in addition, may remain intact on outer sidewalls of spacer 120 after the etching concludes.

Silicide layers 148 then can be formed on the exposed upper surfaces of subcollector 102, extrinsic base 116, and emitter 114. Silicide layers 148 may be formed by depositing a layer of conductive metal (not shown), annealing the conductive metal to cause the metal(s) to migrate into subcollector 102, extrinsic base 116, and emitter 114, and removing any excess metal.

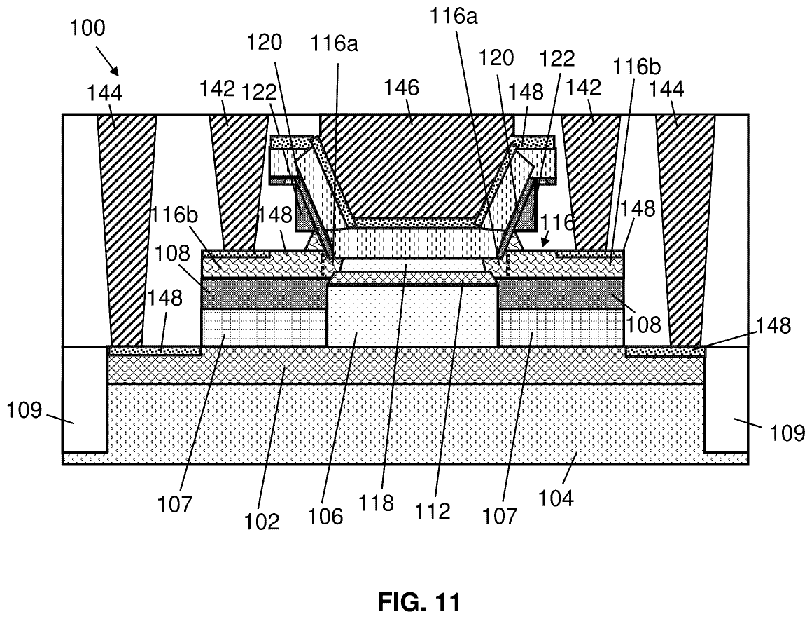

FIG. 11 depicts subsequent processing to provide structure 100. Such processing may include, e.g., forming ILD 140 (FIGS. 1, 2) over the structure, removing portions of ILD 140 located over subcollector 102, extrinsic base 116, and emitter 114, and forming conductor material in the removed portions to provide contacts 142, 144, 146 according to any generally known or applicable processing technique(s). As also discussed herein, contacts 142, 144, 146 may include refractory metal liners (now shown) adjacent to ILD 140 for protection against electromigration degradation. Spacers 120 and spacer protrusions 120, 122 may be present in structure 100 as a result of implementing the various processing techniques discussed herein. Moreover, first portion 116a of extrinsic base 116 has a greater vertical thickness than second portions 116b of extrinsic base 116, e.g., due to the various processes implemented to form extrinsic base 116 and other components of bipolar transistor 110 thereon.

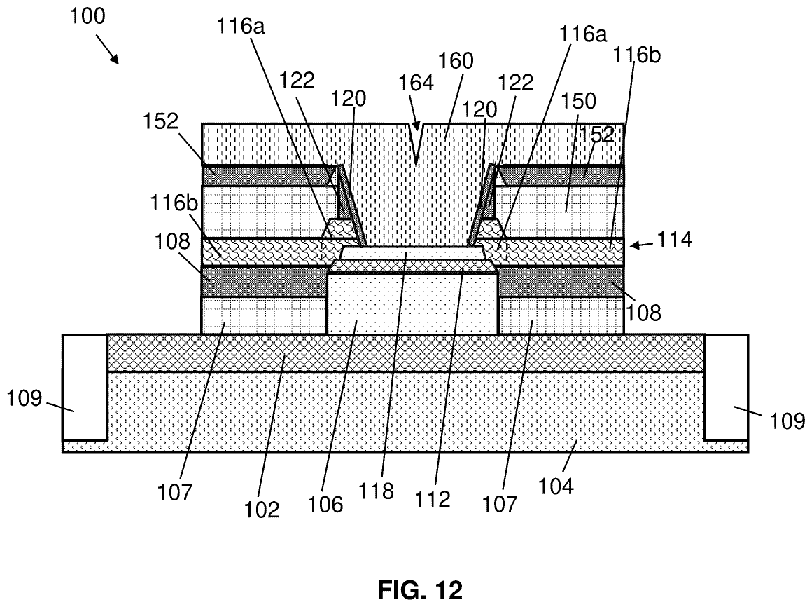

FIGS. 12-14 depict alternative manufacturing techniques to those shown in FIGS. 8-10 and discussed herein, e.g., to provide emitter 114 in a different configuration perhaps with a greater vertical thickness over semiconductor film 118 than in other embodiments. FIG. 12 depicts an intermediate phase of processing after spacers 120 and spacer protrusions have been formed (e.g., following FIG. 7). Here, emitter layer 160 may be formed by deposition to a much greater thickness to fully cover spacer layers 152. Emitter layer 160 and materials thereunder then may be etched back, e.g., such that emitter layer 160 either has a substantially planar upper surface or (optionally) includes a cavity 164 having substantially less depth than opening 154 (FIG. 7). Cavity 164 may arise from, e.g., partial closure of space within emitter layer 160 from forming more polycrystalline semiconductor material than in other embodiments discussed herein.

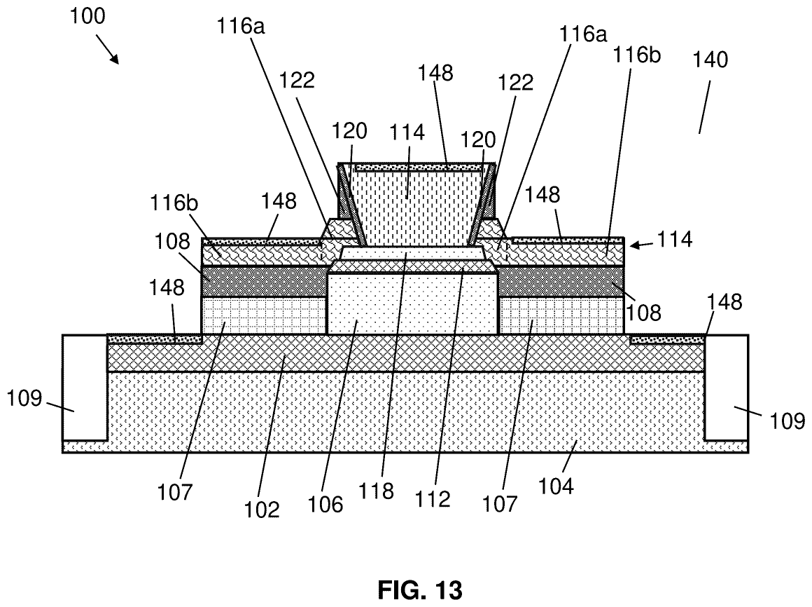

As shown in FIG. 13, methods of the disclosure may include recessing emitter layer 160 and removing adjacent spacer layers 152. In this case, emitter 114 extends to a height above overlying insulator 150, with spacers 120 and spacer protrusions 122 physically separating emitter 114 from overlying insulator 150. The space previously occupied by spacer layer 152, in this case, may remain vacant in subsequent processing. Overlying insulator 150 can then be removed, e.g., by targeted etching of its insulative material(s) through any currently known or later developed technique to remove specific insulators (e.g., selective oxide etching) without affecting spacer 120 and/or spacer protrusion 122. With subcollector 102, emitter 114, and extrinsic base 116 exposed, silicide layers 148 may be formed within these materials by any currently known or later developed technique to form silicide material(s) in active semiconductor material, e.g., those described elsewhere herein.

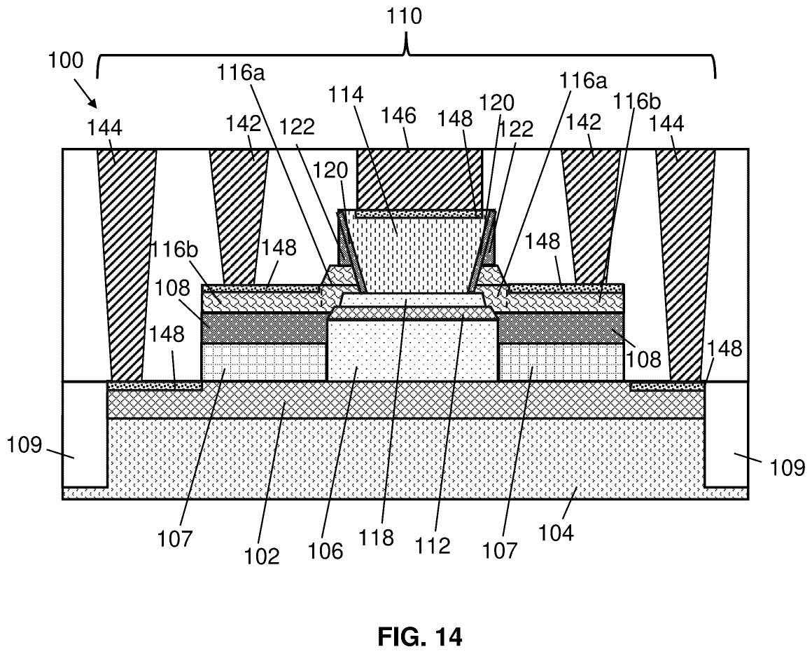

FIG. 14 depicts remaining processes to form structure 100. ILD layer 140 then can be formed over emitter 114 and overlying insulator 150, e.g., by depositing additional insulative materials according to any currently known or later developed process. Openings may be formed within ILD layer 140 and filled with conductor material(s) to create contacts 142, 144, 146. Structure 100 may include spacers 120, spacer protrusions 122, and portions 116a, 116b of extrinsic base 116 with similar or identical features to other implementations. Emitter 114, however, may not be substantially V-shaped or U-shaped and may instead be substantially trapezoidal. Due to the presence of spacer protrusions 122. However, spacers 120 still do not exhibit a substantially linear exterior profile.

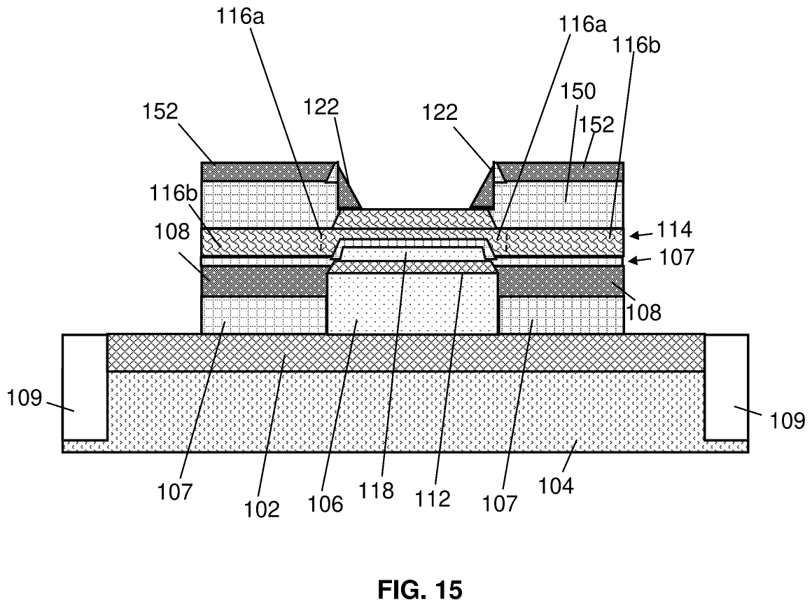

Referring to FIG. 15, further alternative methodologies to form structure 100 (FIGS. 1, 2, 11, 14) according to the disclosure are provided. FIG. 15 illustrates an intermediate structure which may be processed, e.g., using techniques shown in FIGS. 2 and 3 and discussed elsewhere herein. The intermediate structure also may include an additional dielectric layer 107 on dielectric layer 108, such that dielectric layer 108 is sandwiched between dielectric layers 107 in a stacked arrangement. Thus, a portion of dielectric layer 107 extends over and covers semiconductor film 118. After forming spacer layer 152, overlying insulator 150 may optionally be only partially recessed, in which case spacer protrusions 122 may be formed on sidewalls of the partially etched overlying insulator 150. As discussed elsewhere herein, spacer protrusions 122 may be formed by deposition of additional spacer materials and subsequent vertical etching of the deposited materials such that spacer protrusions 122 remain present alongside overlying insulator 150. In subsequent phases of processing, additional portions of overlying insulator 150 may be removed to enable forming of additional spacer protrusions 122 and/or additional intrinsic semiconductor material (similar to semiconductor film 118) to provide additional insulation between terminals and/or greater control over the operational parameters of the eventual bipolar transistor.

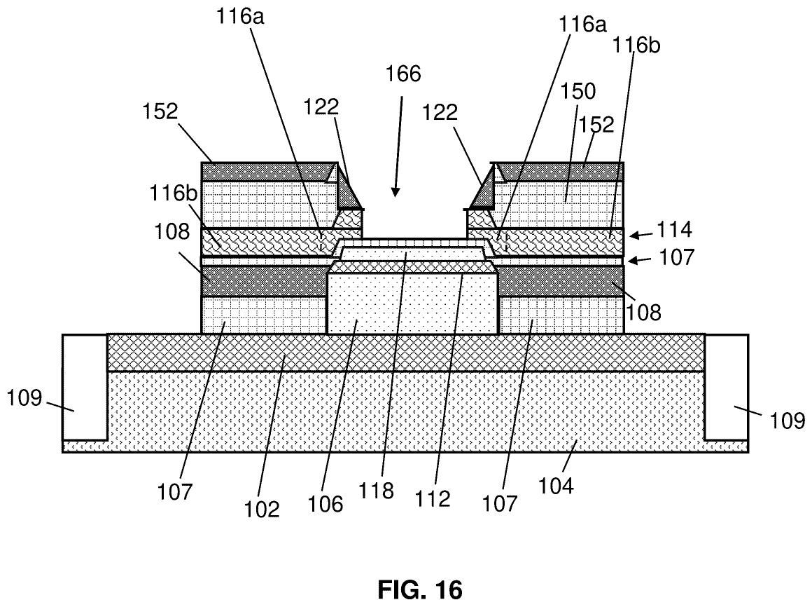

FIG. 16 depicts continued removal of overlying insulator 150, horizontally between spacer protrusions 122. Spacer layers 152 and spacer protrusions 122 may protect other materials from being removed, processed, etc., as portions of overlying insulator 150 are removed. Through the use of vertical etching and/or etchants selective to the composition of overlying insulator 150, embodiments of the disclosure may include forming an inner opening 166 between spacer protrusions 122 to expose the upper surface dielectric layer 107 over semiconductor film 118.

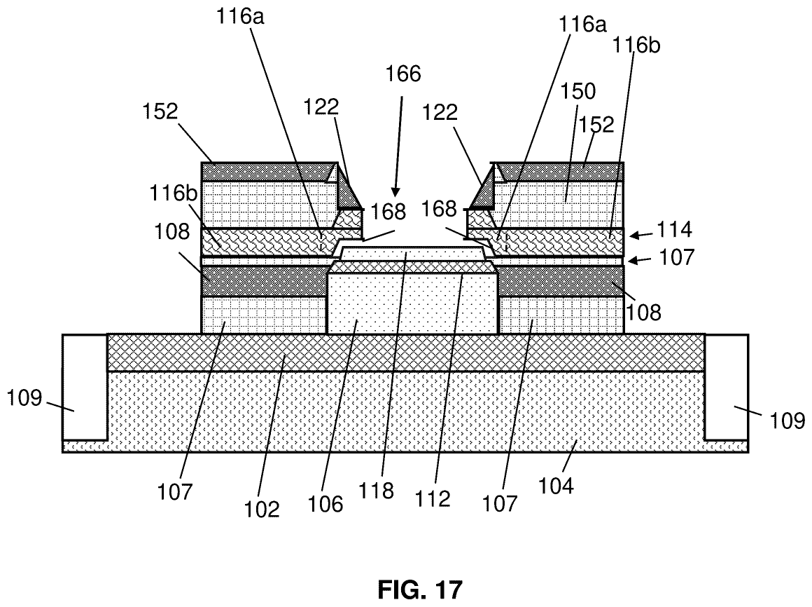

Referring to FIG. 17, the selective removing of insulator layer 107 may continue even after first portion 116a of extrinsic base 116 is exposed. Due to the presence of another insulator layer 107 over semiconductor film 118, continued selective removing of these materials may create cavities 168 alongside semiconductor film 118 above intrinsic base pedestal 112. The forming of cavities 168 may cause a substantially trapezoidal (alternatively, rectangular and/or any other pedestal type shapes) area of semiconductor film 118 to become exposed, such that upper surfaces and sidewalls of semiconductor film 118 are exposed within inner opening 166 and/or cavities 168.

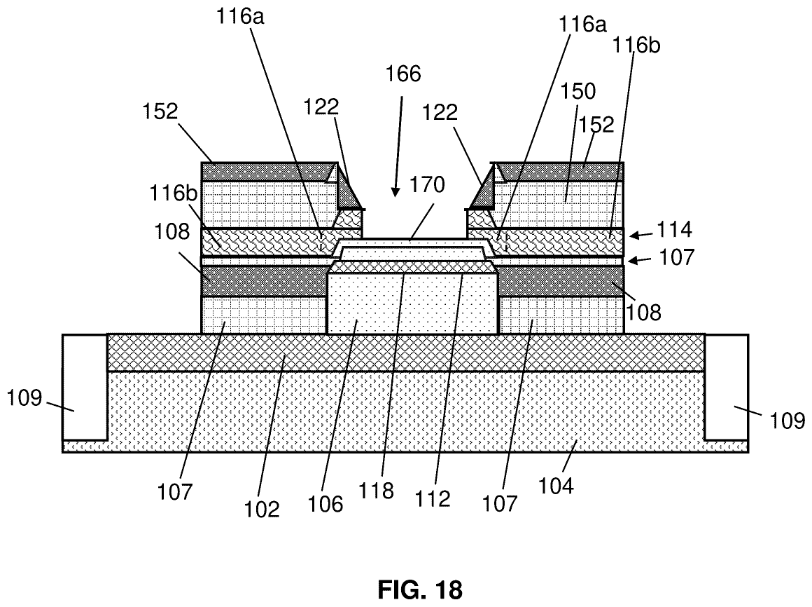

FIG. 18 depicts forming an additional semiconductor film 170 on semiconductor film 118, e.g., by epitaxial growth of intrinsic semiconductor material(s) similar or identical to those used in semiconductor film 118. Additional semiconductor film 170 may be distinct from semiconductor film 118, e.g., by having a larger width and/or physical interface with semiconductor film 118. Additional semiconductor film 170 thus may entirely fill cavity(s) 168 (FIG. 17) and some of the space of inner opening 166. Additional semiconductor film 170 may have a predefined vertical thickness, e.g., such that its upper surface remains below spacer protrusions 122.

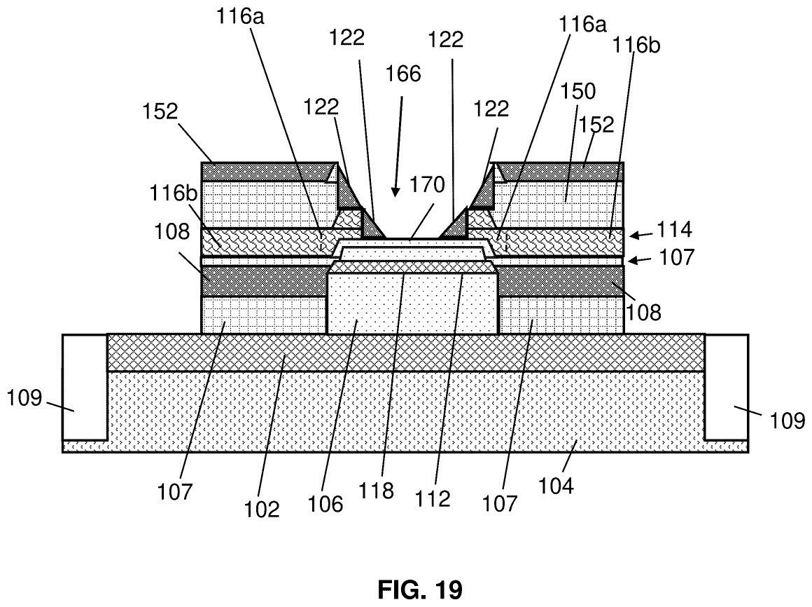

FIG. 19 depicts forming spacer protrusions 122 on additional semiconductor film 170. Spacer protrusions 122 may be formed, e.g., by yet again depositing a layer of spacer material(s) (e.g., nitride-based insulators or similar materials discussed herein) and vertically etching the deposited material(s) such that a portion of those materials remains intact as spacer protrusions 122. According to the example shown, spacer protrusions 122 on additional semiconductor film 170 may be located horizontally inward of any previously formed spacer protrusions 122, and horizontally inward of spacer layer(s) 152. The additional spacer protrusions 122 formed at this stage may help to constrain the horizontal width of the eventual emitter material(s) formed over additional semiconductor film 170, and/or may provide additional electrical isolation.

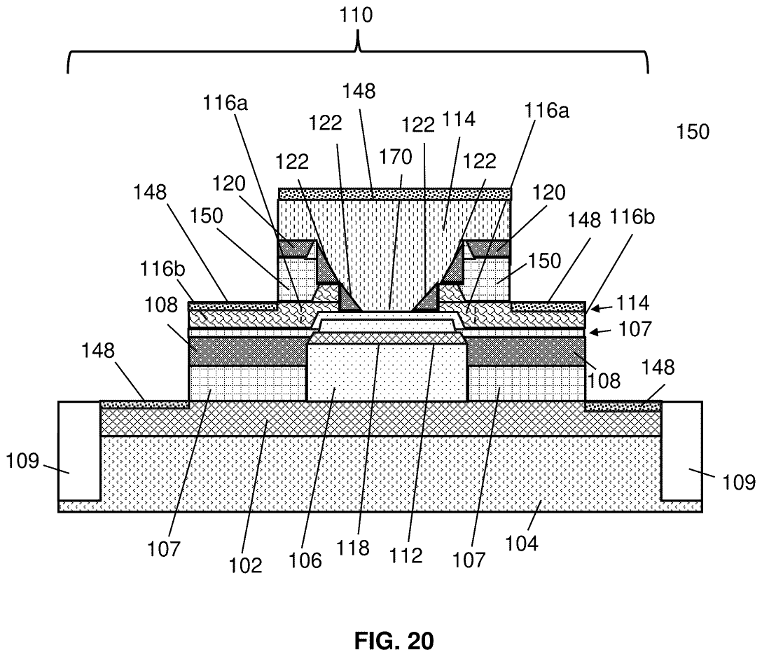

With multiple spacer protrusions 122 in place, FIG. 20 depicts several processes to form the remaining terminals and/or conductive couplings for bipolar transistor 110. Such processes may include, e.g., using a photoresist (not shown) to remove outer portions of spacer layer(s) 152 and overlying insulator 150 thereunder to create spacer(s) 120 adjacent spacer protrusion(s) 122. Additionally, emitter 114 may be formed over additional semiconductor film 170 as well as spacers 120 and spacer protrusions 122. Any exposed portions of subcollector 102, second portion 116b of extrinsic base 116, and emitter 114 may be converted into silicide layers 148 by depositing, annealing, and removing the excess conductive metals as discussed herein.

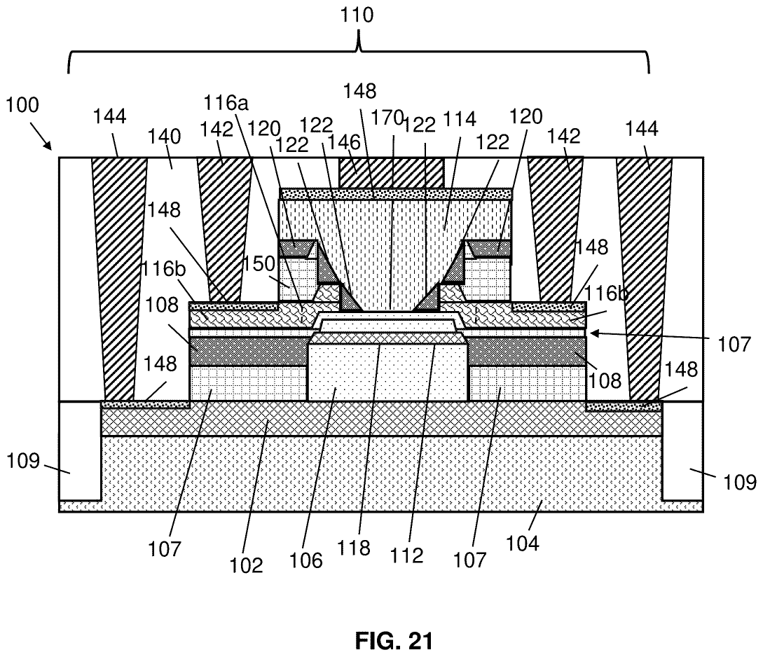

FIG. 21 depicts further processing to form structure 100. As with other embodiments of the disclosure, ILD 140 may be formed over bipolar transistor 110 by deposition. Openings may be formed in ILD 140 and filled with conductive material(s) (and liners, not shown) to provide contacts 142, 144, 146 to each terminal of bipolar transistor 110. Structure 100 may operate substantially identically to other embodiments herein, notwithstanding the presence of additional semiconductor film 170 and a larger number of spacer protrusions 122. Such embodiments of structure 100 may enable, among other things, further customization of operating parameters and/or further electrical isolation between physically proximate components.

Embodiments of the disclosure provide various technical and commercial advantages, examples of which are discussed herein. Embodiments of the disclosure assist fabrication tools and facilities in further decreasing the scale of individual bipolar transistors 110 at desired performance levels, e.g., by using spacer protrusions 122 with spacers 120 to preserve desired amounts of electrical isolation between adjacent active material(s). Embodiments of the disclosure, in addition, avoid the processing challenges of forming similar devices at a similar scale by integrating the forming of spacer protrusions into conventional processes to form emitter(s) 114. For instance, spacer protrusion(s) 122 may be formed at the initial stages of processing to form emitter 114, but before forming the remaining portions of spacer 120. Embodiments of the disclosure also enable forming multiple portions 116a, 116b of extrinsic base 116 with distinct thicknesses to provide additional resistance near intrinsic base pedestal 112 but less electrical resistance near base contacts 146.

The method and structure as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately,” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A structure comprising:
an intrinsic base pedestal on a collector and adjacent a dielectric layer;
a spacer over the intrinsic base pedestal, wherein the spacer extends vertically upward from and horizontally beyond the intrinsic base pedestal, and an emitter is horizontally adjacent the spacer; and
an extrinsic base including:
a first portion vertically between the intrinsic base pedestal and the spacer, and
a second portion on the dielectric layer, wherein a vertical thickness of the second portion is less than a vertical thickness of the first portion.

2. The structure of claim 1, further comprising a spacer protrusion extending horizontally outward from a sidewall of the spacer and vertically above the first portion of the extrinsic base.

3. The structure of claim 2, wherein the spacer protrusion is fully vertically beneath the emitter.

4. The structure of claim 2, wherein the spacer protrusion includes a sloped sidewall adjacent to and extending along an underside of the spacer.

5. The structure of claim 1, further comprising:
the emitter horizontally within the spacer and including a set of sloped sidewalls; and
an emitter contact on the emitter.

6. The structure of claim 1, wherein the second portion of the extrinsic base is vertically below the emitter.

7. The structure of claim 1, wherein the spacer includes a non-linear profile.

8. The structure of claim 1, further comprising a semiconductor film on the first portion of the extrinsic base, wherein the emitter is on the semiconductor film.

9. The structure of claim 8, wherein a lower surface of the spacer is on the semiconductor film.

10. A structure comprising:
a collector on a subcollector and adjacent a dielectric layer;
an intrinsic base pedestal on the collector and adjacent the dielectric layer, wherein the intrinsic base pedestal includes a set of sloped sidewalls;
a spacer over the intrinsic base pedestal, wherein the spacer extends vertically upward from and horizontally beyond the intrinsic base pedestal;
an emitter on the intrinsic base pedestal and horizontally adjacent the spacer; and
an extrinsic base including:
a first portion vertically between the intrinsic base pedestal and the spacer, wherein a lower surface of the first portion of the extrinsic base is adjacent one of the set of sloped sidewalls of the intrinsic base pedestal, and
a second portion on the dielectric layer, wherein a vertical thickness of the second portion is less than a vertical thickness of the first portion.

11. The structure of claim 10, further comprising a spacer protrusion extending horizontally outward from sidewall of the spacer and vertically above the first portion of the extrinsic base.

12. The structure of claim 11, wherein the spacer protrusion is fully vertically beneath the emitter.

13. The structure of claim 11, wherein the spacer protrusion includes a sloped sidewall adjacent to and extending along an underside of the spacer.

14. The structure of claim 10, further comprising a semiconductor film on the first portion of the extrinsic base, wherein the emitter is on the semiconductor film.

15. A method comprising:
forming an intrinsic base pedestal on a collector and adjacent a dielectric layer;
forming a spacer over the intrinsic base pedestal, wherein the spacer extends vertically upward from and horizontally beyond the intrinsic base pedestal, and an emitter is horizontally adjacent the spacer; and
forming an extrinsic base including:
a first portion vertically between the intrinsic base pedestal and the spacer, and
a second portion on the dielectric layer, wherein a vertical thickness of the second portion is less than a vertical thickness of the first portion.

16. The method of claim 15, further comprising forming a spacer protrusion extending horizontally outward from a sidewall of the spacer and vertically above the first portion of the extrinsic base.

17. The method of claim 16, wherein the spacer protrusion is fully vertically beneath the emitter.

18. The method of claim 16, wherein the spacer protrusion includes a sloped sidewall adjacent to and extending along an underside of the spacer.

19. The method of claim 15, further comprising:
forming the emitter horizontally within the spacer, wherein the emitter including a set of sloped sidewalls; and
forming an emitter contact on the emitter.

20. The method of claim 15, wherein the second portion of the extrinsic base is vertically below the emitter.
